(19) United States
(12) Patent Application Publication
(10) Pub. No.: US 2025/0377699 A1
(43) Pub. Date: Dec. 11, 2025

(54) ELECTRONIC DEVICE

(71) Applicant: CARUX TECHNOLOGY PTE. LTD., APERIA (SG)

(72) Inventors: Li-Wei SUNG, Tainan (Tainan Science Park) (TW); Hsin-Fa HSU, Tainan (Tainan Science Park) (TW); Yu-Chun FU, Tainan (Tainan Science Park) (TW); Po-Hao CHEN, Tainan (Tainan Science Park) (TW)

(21) Appl. No.: 19/200,919

(22) Filed: May 7, 2025

(30) Foreign Application Priority Data
Jun. 5, 2024 (CN) 202410723054.4

(51) Int. Cl. G06F 1/18

(52) U.S. Cl. CPC G06F 1/182; G06F 1/183

(57) ABSTRACT

An electronic device is provided. The electronic device includes a display panel, a cover plate, and a plastic layer. The cover plate is disposed relative to the display panel and includes a glass substrate. The plastic layer is disposed around the cover plate, and there is no height difference between the plastic layer and the cover plate.

### CROSS REFERENCE TO RELATED APPLICATIONS

This application claims priority of China Patent Application No. 202410723054.4, filed on Jun. 5, 2024, the entirety of which is incorporated by reference herein.

### BACKGROUND

### Field of the Invention

The present invention relates to an electronic device, and, in particular, to an electronic device that includes a plastic layer disposed around a cover plate.

### Description of the Related Art

Due to the booming development of technology, the usage of electronic devices is becoming more and more popular nowadays. However, existing electronic devices may not be satisfactory in all respects. For example, improvement can still be made with regards to their appearance, display effect, and reliability, etc. Therefore, how to solve the above problem is an important issue.

### BRIEF SUMMARY

An embodiment of the present invention provides an electronic device including a display panel, a cover plate and a plastic layer. The cover plate is disposed relative to the display panel and includes a glass substrate. The plastic layer is disposed around the cover plate, and there is no height difference between the plastic layer and the cover plate.

An embodiment of the present invention provides an electronic device including at least two display panels, at least two cover plates, and a plastic layer. Each of the cover plates is disposed relative to one of the display panels and includes a glass substrate. The plastic layer includes at least one connecting portion, wherein the connecting portion connects the cover plates.

### BRIEF DESCRIPTION OF THE DRAWINGS

The present invention can be more fully understood by reading the subsequent detailed description and examples with references made to the accompanying drawings, wherein:

FIG. 1 shows a schematic perspective view of an electronic device in accordance with some embodiments of the present disclosure.

FIG. 2 shows a partial cross-sectional view of the electronic device in accordance with some embodiments of the present disclosure.

FIG. 3 shows a partial cross-sectional view of the electronic device in accordance with some embodiments of the present disclosure.

FIG. 4 shows a partial perspective view of the electronic device in accordance with some embodiments of the present disclosure.

FIG. 5 shows an exploded view of the electronic device in accordance with some embodiments of the present disclosure.

FIG. 6 shows a partial cross-sectional view of the electronic device in accordance with some embodiments of the present disclosure.

FIG. 7 shows a partial cross-sectional view of the electronic device in accordance with some embodiments of the present disclosure.

FIG. 8 shows a partial cross-sectional view of the electronic device in accordance with some embodiments of the present disclosure.

FIG. 9 shows a partial cross-sectional view of the electronic device in accordance with some embodiments of the present disclosure.

FIG. 10 shows a partial cross-sectional view of the electronic device in accordance with some embodiments of the present disclosure.

### DETAILED DESCRIPTION

The present disclosure may be understood by referring to the following description and the appended drawings. It should be noted that, in order to make it easy for the reader to understand and to make the drawings concise, the drawings in the present disclosure may illustrate a part of the light-emitting unit, and specific elements in the drawings are not drawn based on the actual scale. In addition, the number and the size of each component in the drawings merely serves as an example, and are not intended to limit the scope of the present disclosure. Furthermore, similar and/or corresponding numerals may be used in different embodiments for describing some embodiments simply and clearly, but not represent any relationship between different embodiment and/or structures discussed below.

Certain terms may be used throughout the present disclosure and the appended claims to refer to particular elements. Those skilled in the art will understand that electronic device manufacturers may refer to the same components by different names. The present specification is not intended to distinguish between components that have the same function but different names. In the following specification and claims, the words “including”, “comprising”, “having” and the like are open words, so they should be interpreted as meaning “including but not limited to . . . ”. Therefore, when terms “including”, “comprising”, and/or “having” are used in the description of the disclosure, the presence of corresponding features, regions, steps, operations and/or components is specified without excluding the presence of one or more other features, regions, steps, operations and/or components.

In addition, in this specification, relative expressions may be used. For example, “lower”, “bottom”, “higher” or “top” are used to describe the position of one element relative to another. It should be noted that if a device is flipped upside down, an element that is “lower” will become an element that is “higher”.

When a corresponding component (such as a film layer or region) is referred to as “on another component”, it may be directly on another component, or there may be other components in between. On the other hand, when a component is referred “directly on another component”, there is no component between the former two. In addition, when a component is referred “on another component”, the two components have an up-down relationship in the top view, and this component can be above or below the other component, and this up-down relationship depends on the orientation of the device.

It should be understood that, although the terms “first”, “second” etc. may be used herein to describe various elements, layers and/or portions, and these elements, layers, and/or portions should not be limited by these terms. These terms are only used to distinguish one element, layer, or portion. Thus, a first element, layer or portion discussed below could be termed a second element, layer or portion without departing from the teachings of some embodiments of the present disclosure. In addition, for the sake of brevity, terms such as “first” and “second” may not be used in the description to distinguish different elements. As long as it does not depart from the scope defined by the appended claims, the first element and/or the second element described in the appended claims can be interpreted as any element that meets the description in the specification.

It should be noted that in accordance with the embodiments of the present disclosure, the depth, thickness, width, height, spacing or distance between the elements can be measured by using an optical microscope (OM), scanning electron microscope (SEM), alpha-step (a-step), ellipsometer, or any other suitable method. In accordance with some embodiments, a cross-sectional structure image of the elements to be measured can be captured using a scanning electron microscope, and the depth, thickness, width, height, spacing or distance between the elements can be measured.

In addition, a certain error may be present in a comparison with any two values or directions. The terms “about,” “equal to,” “equivalent,” “the same,” “essentially” or “substantially” are generally interpreted as within 20% of a given value or range, or as interpreted as within 10%, 5%, 3%, 2%, 1%, or 0.5% of a given value or range. In addition, the term “electrically connected” may be used below.

It should be understood that if the present disclosure recites “the first element is electrically connected to the second element,” it may be interpreted as that the first element and the second element are electrically connected to each other and may be synchronously controlled by a single operation, which may include the case “there may be other elements between the first element and the second element to electrically connect the former two,” or include “the first element and the second element are directly electrically connected without other elements.” When it is mentioned in the present disclosure that the first element is “directly electrically connected” to the second element, it may be taken to mean that “the first element and the second element are directly electrically connected without other elements.” In addition, the term “electrically insulated” may be used below. It should be understood that if the present disclosure recites “the first element and the second element are electrically insulated,” it may be interpreted as that the first element and the second element are electrically separated without being connected to each other, nor synchronously controlled by a single operation.

It should be noted that the technical solutions provided by different embodiments below may be interchangeable, combined or mixed to form another embodiment without departing from the spirit of the present disclosure.

Unless defined otherwise, all terms (including technical and scientific terms) used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined in the present disclosure.

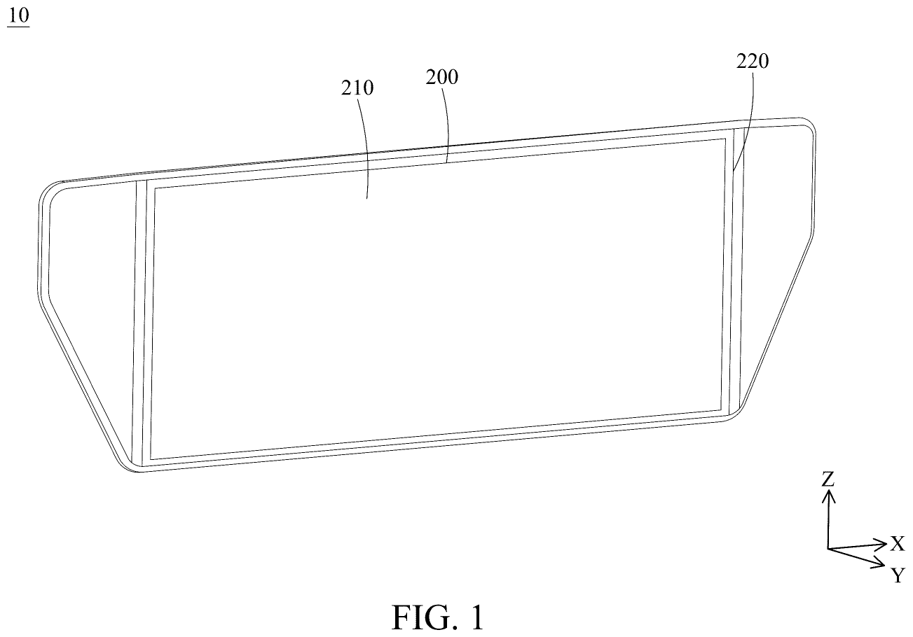

FIG. 1 shows a schematic perspective view of an electronic device 10 in accordance with some embodiments of the present disclosure. The electronic device 10 may include, for example, a display device, a splicing device, a touch electronic device, a sensing device, an antenna device, a package device, a curved electronic device or a non-rectangular electronic device, but the present disclosure is not limited thereto. The electronic device 10 may include, for example, a liquid crystal, a light-emitting diode (LED), fluorescence, phosphor, other suitable display media, or a combination thereof. The display device may be a non-self-luminous display device or a self-luminous display device. The electronic device 10 may include electronic components, and the electronic components may include passive components and active components, such as capacitors, resistors, inductors, diodes, drive components, transistors, etc. The diodes may include light-emitting diodes or photodiodes. The light-emitting diodes may, for example, include organic light-emitting diodes (OLEDs), mini LEDs, micro LEDs or quantum dot LEDs, but the present disclosure is not limited thereto. The splicing device may be, for example, a display splicing device or an antenna splicing device, but the present disclosure is not limited thereto. The antenna device may be a liquid-crystal antenna device or a varactor diodes antenna device. The package device may be applicable to wafer-level packaging (WLP) technique or panel-level packaging (PLP) technique, such as chip first process or redistribution layer (RDL) first process. It should be noted that the electronic device 10 may be any combination of the above-mentioned devices, but the present disclosure is not limited thereto. In addition, the electronic device 10 may be a bendable or flexible electronic device. In addition, the shape of the electronic device 10 may be rectangular, circular, polygonal, shapes with curved edges or other suitable shapes. The electronic device 10 may have peripheral systems such as drive systems, control systems, light-source systems, and rack systems, etc. to support display devices or splicing devices.

The following paragraphs will describe the content of the present disclosure with respect to the partial structure of the electronic device 10, but the present disclosure is not limited thereto. It should be understood by those skilled in the art that the electronic device 10 may also include other structures or be provided with suitable electronic components to perform the desired functions.

As shown in FIG. 1, the electronic device 10 may include a display panel (not shown in this embodiment) and a cover plate 200 disposed relative to the display panel. In some embodiments, the cover plate 200 may include a glass substrate 210, but the present disclosure is not limited thereto. In addition, the electronic device 10 may include a plastic layer 220 that is disposed around the cover plate 200. For example, the material of the plastic layer 220 may include polymethyl methacrylate (PMMA), polycarbonate (PC), acrylonitrile butadiene styrene (ABS), acrylonitrile styrene acrylate (ASA), resin or other suitable plastic materials, but the present disclosure is not limited thereto. The plastic layer 220 is disposed around the cover plate 200 (including the glass substrate 210), and there is substantially no height difference between the plastic layer 220 and the cover plate 200 (including the glass substrate 210). Since the glass substrate 210 has high hardness and relatively high reflectivity, better display effects and reliability can be obtained. In contrast, the plastic layer 220 is easy to shape, and therefore the manufacturing difficulty of the electronic device 10 and/or the impact of external force on the glass substrate can be reduced. The detailed structures of the glass substrate 210 and the plastic layer 220 will be further described below. It should be understood that other film or layers can be disposed on the glass substrate 210 or various processing processes can be performed on the glass substrate 210, and these derivative embodiments are also included within the scope of the present disclosure. In some embodiments, the number and shape of the display panels and the cover plate 200 are not limited by the drawings of this disclosure and are adjustable as required.

In addition, it should be understood that the components or elements that are the same or similar to those mentioned above will be represented by the same or similar numerals below, and their materials and functions are the same or similar as those mentioned above, so this part will not be discussed in detail below.

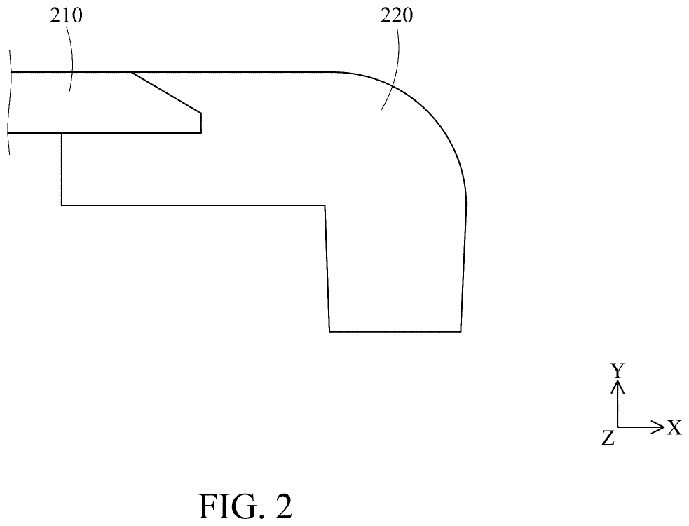

FIG. 2 shows a partial cross-sectional view of the electronic device 10 in accordance with some embodiments of the present disclosure. It should be noted that in order to focus on the structure of the glass substrate 210 and the plastic layer 220, this embodiment does not illustrate the display panel. As shown in FIG. 2, the glass substrate 210 may have a top surface 211 and sidewalls 212 that are connected to the top surface 211. In some embodiments, an obtuse angle can be formed between the top surface 211 and the sidewalls 212 (that is, the sidewalls 212 are inclined relative to the normal direction of the top surface 211), thereby increasing the contact area between the glass substrate 210 and the plastic layer 220 and/or mitigating the impact of external force on the glass substrate 210. In some embodiments, the plastic layer 220 can be bonded to the cover plate 200 by injection molding. For example, glass insert molding (GIM) may be adopted to bond the plastic layer 220 to the sidewalls 212 of the glass substrate 210. The inclination of the sidewalls 212 increases the contact area between the glass substrate 210 and the plastic layer 220, thereby improving the bonding strength of the glass substrate 210 and the plastic layer 220 and/or mitigating the impact of external forces on the glass substrate 210. In some embodiments, there is substantially no height difference between the plastic layer 220 and the cover plate 200. In other words, the top surface of the plastic layer 220 and the top surface 211 of the glass substrate 210 are substantially coplanar. It should be understood that slight errors caused by process variations do not violate the teachings of the present disclosure. With the above features, the appearance of the electronic device 10 can be optimized and the convenience of use can be improved.

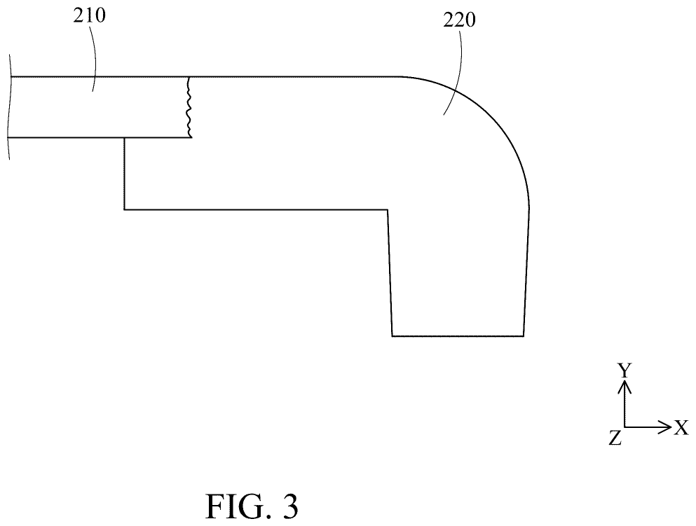

FIG. 3 shows a partial cross-sectional view of the electronic device 10 in accordance with some embodiments of the present disclosure. It should be noted that the electronic device 10 in this embodiment may include the same or similar structures or portions as the electronic device 10 shown in FIG. 2. These structures or portions will be denoted by the same or similar numerals, and for the sake of brevity, these structures or portions will not be discussed in detail below. As shown in FIG. 3, the top surface 211 and the sidewalls 212 of the glass substrate 210 can be perpendicular to each other, but the sidewalls 212 can be roughened (for example, by etching, grinding or other similar methods). This configuration can increase the contact area between the glass substrate 210 and the plastic layer 220, thereby improving the bonding strength of the glass substrate 210 and the plastic layer 220, and/or mitigating the impact of external forces on the glass substrate.

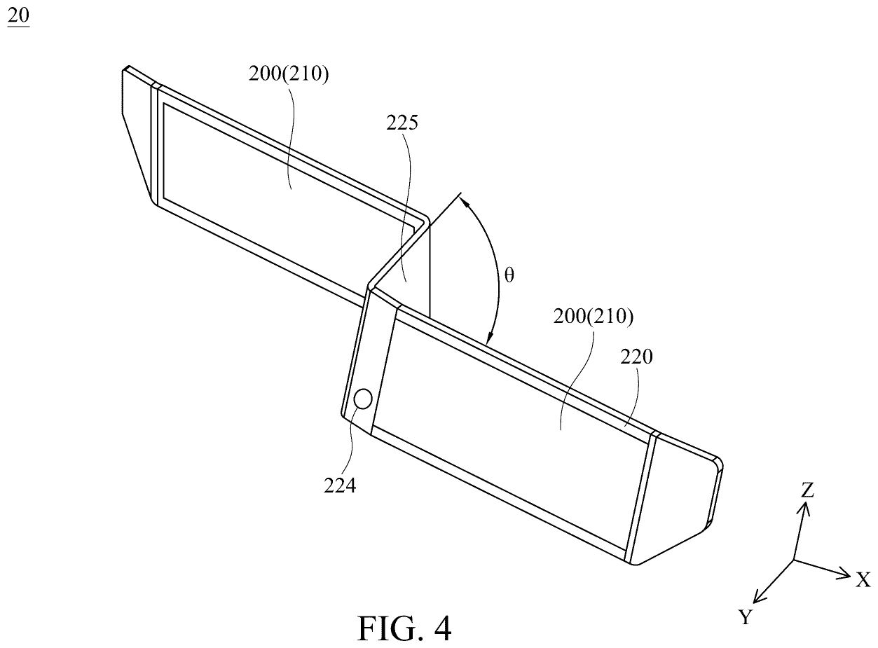

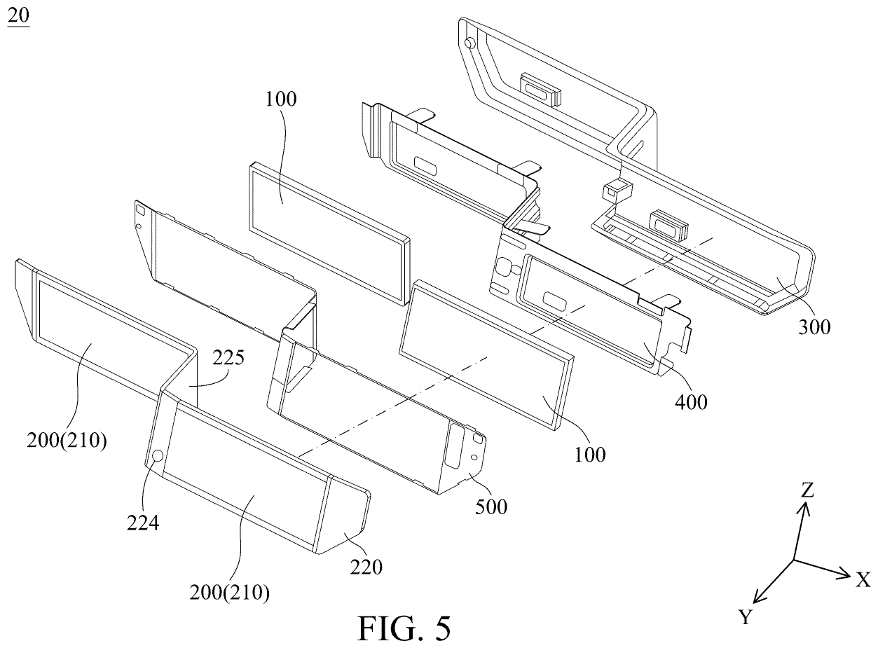

FIG. 4 shows a partial perspective view of the electronic device 20 in accordance with some embodiments of the present disclosure. FIG. 5 shows an exploded view of the electronic device 20 in accordance with some embodiments of the present disclosure. It should be noted that the electronic device 10 in this embodiment may include the same or similar structures or portions as the electronic device 10 shown in FIG. 2. These structures or portions will be denoted by the same or similar numerals, and for the sake of brevity, these structures or portions will not be discussed in detail below. As shown in FIGS. 4 and 5, the electronic device 20 may include at least two display panels 100, at least two cover plates 200, a plastic layer 220, a base 300 and a frame 400. In some embodiments, the display panel 100 is disposed over the base 300 and the frame 400. In some embodiments, the display panel 100 may include a substrate and polarizing films (not shown individually), wherein the polarizing films may be located on the upper and lower sides of the substrate. For example, the substrate may be a flexible substrate or a non-flexible substrate. The material of the substrate may include glass, sapphire, ceramics, plastic, or other suitable materials. The plastic material may be, for example, polyimide (PI), polyethylene terephthalate (PET), polycarbonate (PC), polyether oxime (PES), polybutylene terephthalate (PBT), polynaphthalene ethylene glycolate (PEN), or polyarylate (PAR), other suitable materials, or combinations thereof, but the present disclosure is not limited thereto. In some embodiments, a liquid-crystal layer (not shown) may be disposed in the display panel 100, and the liquid-crystal layer may include nematic liquid crystal, smectic liquid crystal, cholesteric liquid crystal, blue phase liquid crystal, or any other suitable liquid-crystal material.

In some embodiments, each of the cover plates 200 is disposed relative to one of the display panel 100 and includes a glass substrate 210. The plastic layer 220 includes at least one connecting portion 225 to connect the cover plates 200. In some embodiments, the connecting portion 225 is bendable and connects the non-parallel cover plates 200. For example, an included angle θ may be formed between the connecting portion 225 and one of the cover plates 200. In some embodiments, the included angle θ may be an obtuse angle (i.e., greater than about 90°). In this way, the manufacturing difficulty of the electronic device 20 can be reduced, and the electronic device 20 can meet various design requirements. In some embodiments, the connecting portion 225 and other parts of the plastic layer 220 may be integrally formed, but the present disclosure is not limited thereto. In some embodiments, there is substantially no height difference between the plastic layer 220 and the cover plate 200. As a result, the manufacturing steps of the electronic device 20 can be reduced. In other embodiments, the connecting portion 225 and other parts of the plastic layer 220 belong to different components, and can be bonded to the plastic layer 220 in any suitable manner. For example, the connecting portion 225 can be bonded to the plastic layer 220 via adhesion, fastening, locking (such as using screws), etc., but the present disclosure is not limited thereto. As a result, the manufacturing difficulty of the electronic device 20 can be reduced. In some embodiments, the plastic layer 220 further includes at least one opening 224, which can be configured to install additional components of the electronic device 20, but the present disclosure is not limited thereto.

In addition, the base 300 and the frame 400 can be configured to support the display panel 100, thereby optimizing the appearance of the electronic device 20. In addition, the above features can also protect the display panel 100 from being damaged by moisture, dust, etc. For example, the material of the base 300 may include plastic materials, and the material of the frame 400 may include metal materials, but the present disclosure is not limited thereto. In some embodiments, the electronic device 20 may optionally include a bracket 500. In addition, the bracket 500 can be connected to the cover plate 200 via an adhesive (not shown). Such configuration can reduce the gap between the base 300 and the cover plate 200 and further protect the display panel 100. In some embodiments, the adhesive may be optical clear adhesive (OCA), but the present disclosure is not limited thereto.

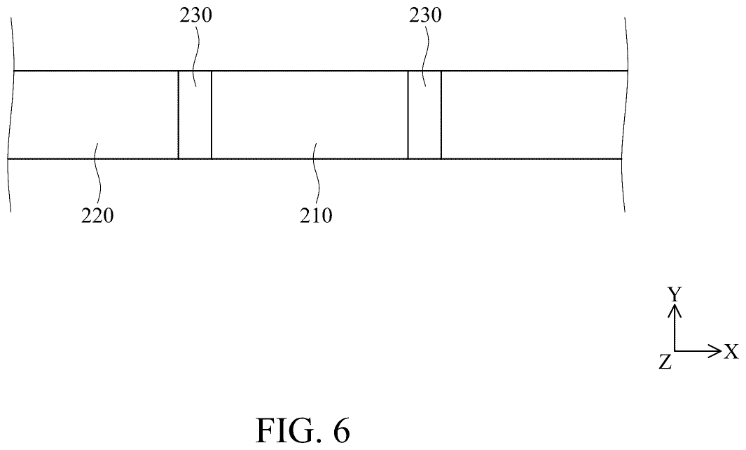

FIG. 6 shows a partial cross-sectional view of the electronic device 20 in accordance with some embodiments of the present disclosure. As shown in FIG. 6, the glass substrate 210 can be assembled to the plastic layer 220. In some embodiments, a buffer member 230 is disposed between the plastic layer 220 and the cover plate 200 (such as the glass substrate 210). Specifically, the buffer member 230 may contact and bond the plastic layer 220 and the cover plate 200, thereby providing buffering between the plastic layer 220 and the cover plate 200, and reducing the risk of the cover plate 200 being damaged by external force. For example, the buffer member 230 may include rubber, but the present disclosure is not limited thereto. In some embodiments, a light-shielding layer (not shown) can be disposed between the plastic layer 220 and the cover plate 200 (such as the glass substrate 210), thereby improving the display effect of the electronic device 20.

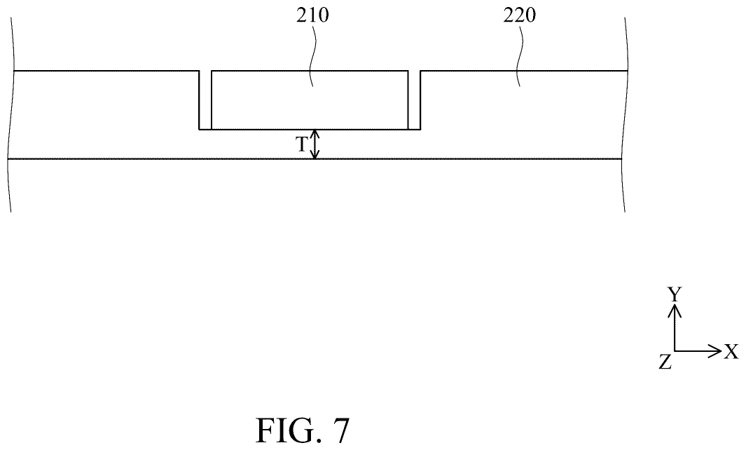

FIG. 7 shows a partial cross-sectional view of the electronic device 20 in accordance with some embodiments of the present disclosure. It should be noted that the electronic device 20 in this embodiment may include the same or similar structures or portions as the electronic device 20 shown in FIG. 6. These structures or portions will be denoted by the same or similar numerals, and for sake of brevity, these structures or portions will not be discussed in detail below. As shown in FIG. 7, the cover plate 200 (such as the glass substrate 210) can be disposed on the plastic layer 220 (for example, located in a recess of the plastic layer 220). For example, the thickness T of the plastic layer 220 below the cover plate 200 can be greater than or equal to about 0.8 mm, thereby providing sufficient support for the cover plate 200. For example, the thickness T can be measured along the normal direction of the cover plate 200 (such as the Y direction), but the present disclosure is not limited thereto. In some embodiments, a gap is formed between the glass substrate 210 and the plastic layer 220, but the present disclosure is not limited thereto. With the above features, a buffer space can be provided between the plastic layer 220 and the cover plate 200, thereby reducing the risk of the cover plate 200 being damaged by external force. In other embodiments, the glass substrate 210 may contact the plastic layer 220.

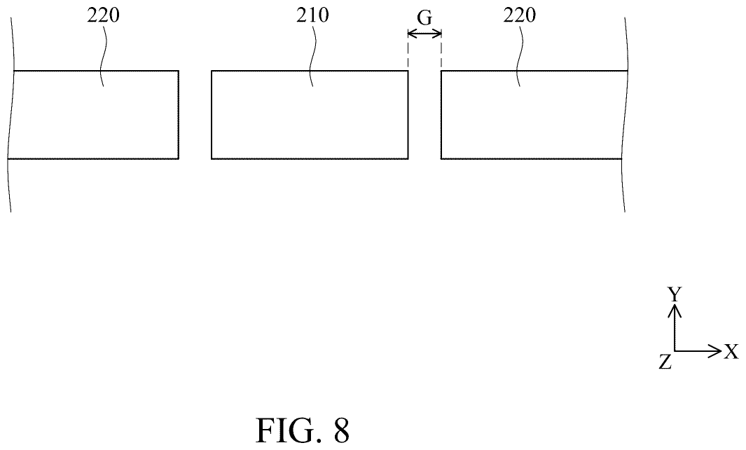

FIG. 8 shows a partial cross-sectional view of the electronic device 20 in accordance with some embodiments of the present disclosure. It should be noted that the electronic device 20 in this embodiment may include the same or similar structures or portions as the electronic device 20 shown in FIG. 6. These structures or portions will be denoted by the same or similar reference numerals, and for sake of brevity, these structures or portions will not be discussed in detail below. As shown in FIG. 8, a gap G is formed between the glass substrate 210 and the plastic layer 220, thereby providing a buffer space between the plastic layer 220 and the cover plate 200, thereby reducing the risk of the cover plate 200 being damaged by external force. In some embodiments, the gap G may be less than or equal to about 0.3 mm, but the present disclosure is not limited thereto. For example, the gap G may be measured along a direction parallel to the top surface of the cover plate 200 (such as the X direction), but the present disclosure is not limited thereto.

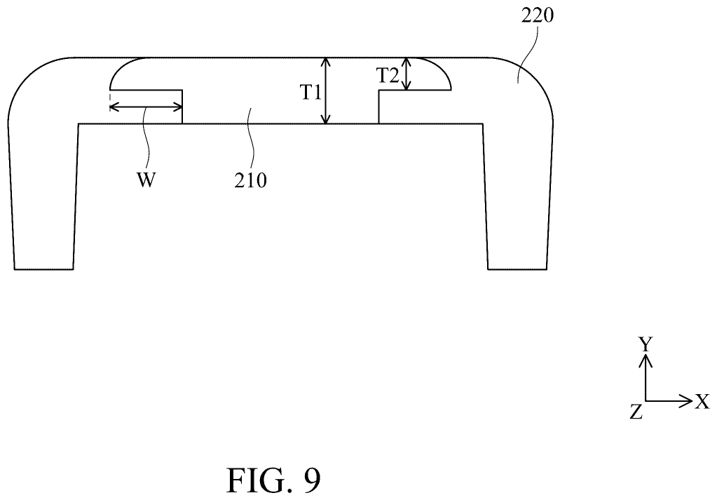

FIG. 9 shows a partial cross-sectional view of the electronic device 20 in accordance with some embodiments of the present disclosure. It should be noted that the electronic device 20 in this embodiment may include the same or similar structures or portions as the electronic device 20 shown in FIG. 6. These structures or portions will be denoted by the same or similar numerals, and for sake of brevity, these structures or portions will not be discussed in detail below. As shown in FIG. 9, the glass substrate 210 has a first thickness T1 and a second thickness T2. To be more specific, the glass substrate 210 has the first thickness T1 in the central portion and the second thickness T2 in the peripheral portion. The first thickness T1 may be greater than or equal to the second thickness T2. For example, the first thickness T1 and the second thickness T2 may be measured along the normal direction of the cover plate 200 (such as the Y direction). However, the present disclosure is not limited thereto. In some embodiments, the ratio of the first thickness T1 to the second thickness T2 is from about 1 to about 3 (1≤T1/T2≤3). In some embodiments, the distance W between the edge of the central portion and the edge of the peripheral portion may be from about 10 mm to about 20 mm. For example, the distance W may be measured along a direction parallel to the top surface of the cover plate 200 (such as the X direction), but the present disclosure is not limited thereto. In summary, the contact area between the glass substrate 210 and the plastic layer 220 can be increased, the bonding strength of the glass substrate 210 and the plastic layer 220 can be improved, and/or the impact of external force on the glass substrate can be mitigated. Specifically, the plastic layer 220 can extend above the peripheral portion of the glass substrate 210, and there is substantially no height difference between the plastic layer 220 and the cover plate 200 (i.e., the glass substrate 210), thereby optimizing the appearance of the electronic device 20 and improving the convenience of use. In some embodiments, the glass substrate 210 can be made via thermal bending, computer numerical control (CNC) processing, and/or other suitable methods.

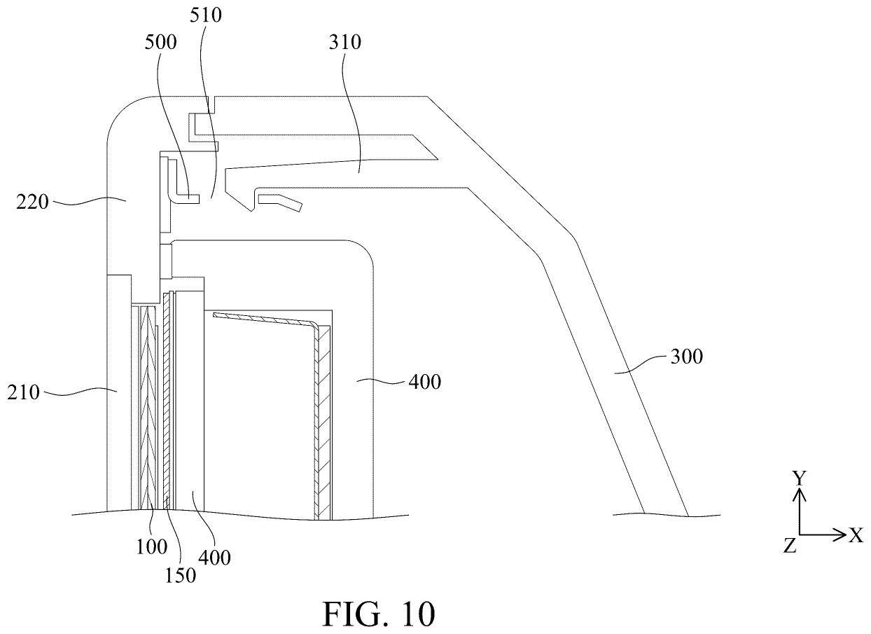

FIG. 10 shows a partial cross-sectional view of the electronic device 20 in accordance with some embodiments of the present disclosure. As shown in FIG. 10, the base 300 may include a hook structure 310 that passes through the positioning portion 510 of the bracket 500. In this way, the base 300 and the bracket 500 can be firmly bonded, and the gap between the base 300 and the cover plate 200 can be reduced to protect the display panel 100. In some embodiments, the electronic device 20 may include a diffusion plate 140 and an optical film 150. For example, the optical film 150 may include a lower diffusion film, an upper diffusion film, a lower light-enhancing film, an upper light-enhancing film, a prism, a reverse prism, etc., but the present disclosure is not limited thereto. In some embodiments, an adhesive member (not shown) may be disposed between the optical film 150 and the diffusion plate 140 to attach the optical film 150 to the diffusion plate 140 for simplifying the assembly processes. However, the process disclosure is not limited thereto. In some embodiments, the display panel 100 is bonded to the electronic device 20 via the optical adhesive, and then bonded to the frame 400 (including the optical film 150). In this way, the difficulty of the manufacturing process can reduced. In some embodiments, the display panel 100 can be directly bonded to the frame 400 (including the optical film 150), and then bonded to the electronic device 20 via the optical adhesive, but the present disclosure is not limited thereto.

It should be understood that although the above embodiments merely illustrate part of the configuration of the electronic device, those skilled in the art should be able to add other optical layers and/or light-emitting elements to the structures herein based on the teachings of the present disclosure for the purpose of enhancing the display and/or touch effects. These configurations derived from the present disclosure are also included within the scope of the present disclosure. In addition, the present disclosure also provides several different electronic devices. Those skilled in the art should be able to arbitrarily combine/arrange these electronic devices without violating the teachings of the present disclosure, and these arrangements and combinations are all included within the scope of the present disclosure.

As set forth above, the embodiments of the present disclosure provide an electronic device including a plastic layer that is disposed around the cover plate. Specifically, better display effects and reliability can be obtained using the glass substrate, and the plastic layer can make the electronic device easy to shape and/or can mitigate the impact of external forces on the glass substrate. In this way, the difficulty of manufacturing the electronic device may be reduced. As a result, the advantages of each material can be utilized at the same time to achieve the best display effect. In addition, there is substantially no height difference between the plastic layer and the cover plate, thereby optimizing the appearance of the electronic device and improving the convenience of use. In addition, multiple cover plates can be connected via the connecting portion, so that the electronic device can meet various design requirements.

While the embodiments and the advantages of the present disclosure have been described above, it should be understood that those skilled in the art may make various changes, substitutions, and alterations to the present disclosure without departing from the spirit and scope of the present disclosure. It should be noted that different embodiments may be arbitrarily combined as other embodiments as long as the combination conforms to the spirit of the present disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

What is claimed is:

1. An electronic device, comprising:
a display panel;
a cover plate disposed relative to the display panel and comprising a glass substrate; and
a plastic layer, wherein the plastic layer is disposed around the cover plate, and there is no height difference between the plastic layer and the cover plate.

2. The electronic device as claimed in claim 1, wherein the plastic layer is bonded to the cover plate by injection molding.

3. The electronic device as claimed in claim 1, comprising a buffer member and/or a light-shielding layer disposed between the plastic layer and the cover plate.

4. The electronic device as claimed in claim 1, wherein the glass substrate has a first thickness and a second thickness, and a ratio of the first thickness to the second thickness is from about 1 to about 3.

5. The electronic device as claimed in claim 1, wherein the plastic layer further comprises at least one opening.

6. The electronic device as claimed in claim 1, wherein the material of the plastic layer comprises polymethyl methacrylate (PMMA), polycarbonate (PC), acrylonitrile butadiene styrene (ABS), acrylonitrile styrene acrylate (ASA), or resin.

7. The electronic device as claimed in claim 1, wherein an obtuse angle is formed between a top surface of the glass substrate and a sidewall of the glass substrate.

8. The electronic device as claimed in claim 1, wherein a top surface of the glass substrate and a sidewall of the glass substrate is perpendicular to each other, and the sidewall is roughened.

9. An electronic device, comprising:
at least two display panels;
at least two cover plates, each of the at least two cover plates is disposed relative to one of the at least two display panels and comprising a glass substrate; and
a plastic layer comprising at least one connecting portion, wherein the connecting portion connects the at least two cover plates.

10. The electronic device as claimed in claim 9, wherein there is no height difference between the plastic layer and the at least two cover plates.

11. The electronic device as claimed in claim 9, wherein an included angle is formed between the at least one connecting portion and the at least two cover plates.

12. The electronic device as claimed in claim 9, wherein the at least one connecting portion is bendable.

13. The electronic device as claimed in claim 9, wherein the glass substrate has a first thickness and a second thickness, and the ratio of the first thickness to the second thickness is from about 1 to about 3.

14. The electronic device as claimed in claim 9, comprising a frame configured to support the display panel 100, wherein a material of the frame 400 comprises metal materials.

15. The electronic device as claimed in claim 14, comprising a diffusion plate and an optical film connected to the frame and bonded to the at least two display panels.

16. The electronic device as claimed in claim 9, comprising a base configured to support the display panel, wherein a material of the base comprises plastic materials.

17. The electronic device as claimed in claim 16, comprising a bracket connected to each of the at least two cover plates via an adhesive.

18. The electronic device as claimed in claim 17, wherein the base comprises a hook structure passing through a positioning portion of the bracket.

19. The electronic device as claimed in claim 9, wherein a thickness of the plastic layer below each of the at least two cover plates is greater than or equal to about 0.8 mm.

20. The electronic device as claimed in claim 9, wherein a gap is formed between the glass substrate and the plastic layer, and the gap is less than or equal to about 0.3 mm.
